(19) United States
(12) Patent Application Publication
(10) Pub. No.: US 2020/0127090 A1
(43) Pub. Date: Apr. 23, 2020

(54) Wide-Gap Semiconductor Substrate, Apparatus For Manufacturing Wide-Gap Semiconductor Substrate, And Method For Manufacturing Wide-Gap Semiconductor Substrate

(71) Applicant: SPP TECHNOLOGIES CO., LTD., Tokyo (JP)

(72) Inventor: Takashi YAMAMOTO, Hyogo (JP)

(73) Assignee: SPP TECHNOLOGIES CO., LTD., Tokyo (JP)

(21) Appl. No.: 16/629,085

(22) PCT Filed: Dec. 13, 2018
(86) PCT No.: PCT/JP2018/045825

§ 371 Date: Jan. 7, 2020

(30) Foreign Application Priority Data
Jan. 17, 2018 (JP) 2018-005923

(51) Int. Cl. H01L 29/06; H01L 29/16; H01L 29/20; H01L 29/24; H01L 21/67; H01L 21/3065

(52) U.S. Cl. CPC H01L 29/0657; H01L 29/1608; H01L 29/1602; H01L 21/3065; H01L 29/24; H01L 21/67069; H01L 21/67253; H01L 29/2003

(57) ABSTRACT

Provided is a method for manufacturing a wide-gap semiconductor substrate enabling formation of a device having low power loss while maintaining high mechanical strength. This method is an etching method for etching a wide-gap semiconductor substrate (W) placed on a platen (15) disposed in a processing chamber (11) by means of plasma generated from an etching gas so that only a device formation region of the wide-gap semiconductor substrate (W) is thinned, the method including a step of supplying the etching gas into the processing chamber (11) and generating the plasma from the etching gas, and a step of applying a bias potential to the platen (15) to etch only the device formation region of the wide-gap semiconductor substrate (W) so as to thin only the device formation region.

### TECHNICAL FIELD

The present invention relates to a wide-gap semiconductor substrate for forming a device on a surface thereof, an apparatus for manufacturing a wide-gap semiconductor substrate, and a method for manufacturing a wide-gap semiconductor substrate.

### BACKGROUND ART

In recent years, electronic devices have been reduced in size, thickness, and weight, reduced in power loss (enhanced in efficiency), and enhanced in functionality (performance). Accordingly, a thin semiconductor device has been developed which is manufactured with a thinned silicon substrate. Particularly, a vertical power device has lower power loss when a silicon substrate (wafer) is thinner; therefore, it is preferred that such a device is manufactured with a silicon substrate having a minimum thickness with necessary voltage withstanding property. To this end, in manufacturing a thin power device, a silicon substrate is thinned to a desired thickness by grinding a back surface, i.e., a surface opposite to a surface on which functional layers are formed, of the silicon substrate. However, there are problems that the silicon substrate is cracked or chipped due to warpage occurring in thinning the silicon substrate and that the thinned silicon substrate is cracked when being conveyed. To solve these problems, for example, a technology is disclosed in Patent Literature 1 (Japanese Patent No. 6004100) in which a back surface of a silicon substrate is thinned by grinding only an inner area of the back surface of the silicon substrate with a peripheral area thereof left ungrinded. This technology enables reduction of cracking and warpage of the silicon substrate.

Simultaneously, power devices are further required to have low on-state resistance and high withstand voltage. To meet these requirements, manufacture using a silicon carbide substrate instead of using a conventionally used silicon substrate has attracted attention. Silicon carbide has smaller crystal lattice constant (stronger interatomic bonding) than silicon, and has a band gap (2.2 eV or more, hereinafter referred to as “wide gap”) greater than a band gap of silicon (1.12 eV). Further, a silicon carbide substrate has dielectric breakdown field strength (unit: V/cm) approximately 10 times as high as that of a silicon substrate. That is to say, in the case of using a silicon carbide substrate instead of a silicon substrate to manufacture an equivalent voltage withstanding product (device), a silicon carbide substrate having a thickness equal to only one tenth of that of the silicon substrate is used. For example, provided that a silicon carbide substrate has a withstand voltage of 100 V/μm, a silicon carbide substrate having a thickness of 15 μm can be used for a device having a withstanding voltage of 1200 V that is lower than 1500 V. On the other hand, in the case of using a silicon substrate to obtain an equivalent withstand voltage, the silicon substrate has to have a thickness of about 150 μm. Therefore, in the case where a silicon carbide substrate is used to manufacture a device having a required withstand voltage, it is preferred that the silicon carbide substrate has a thickness equal to one tenth of a thickness a silicon substrate is required to have to manufacture the device. Such a device is manufactured as follows: functional layers are formed on a surface of a silicon carbide substrate and then areas marked off by predetermined division lines are formed on the functional layers; subsequently, the silicon carbide substrate is thinned to a predetermined thickness by grinding a back surface of the silicon carbide substrate with a grinding device; and thereafter the silicon carbide substrate is divided into device chips by cutting the silicon substrate along the predetermined division lines with a cutting device, a laser processing device, or the like. The divided devices chips are each used for a power device.

### CITATION LIST

### Patent Literature

[Patent Literature 1] Japanese Patent No. 6004100

### SUMMARY OF INVENTION

### Technical Problem

For example, Patent Literature 1 discloses a wafer thinning technology in which a wafer reinforced by a support substrate that is affixed to the wafer is entirely thinned with a grinding device. However, as described in Patent Literature 1, using a grinding device has a problem that, if the wafer is to be thinned to an extremely small thickness (for example, 50 μm or less, which depends on the material of the wafer), the wafer is cracked or warped. Further, in the case where the wafer is a wide-gap semiconductor substrate made of silicon carbide or the like, the wafer has much higher hardness than a silicon substrate. Therefore, there is a problem that, when the back surface of the wafer is grinded with a grinding wheel including abrasives, the abrasives are worn out 4 to 5 times as much as the amount of grinding, which is very uneconomical. For example, abrasives are worn out by 0.1 μm when grinding a silicon substrate by 100 μm. On the other hand, abrasives are worn out by 400 to 500 μm when grinding a silicon carbide substrate by 100 μm; thus, abrasives are worn out 4000 to 5000 times as much as in the case of grinding a silicon substrate.

Further, Patent Literature 1 proposes that, in the case of thinning a wafer made of silicon carbide (SiC), the wafer is thinned by CMP because a SiC wafer cannot be melted. However, polishing a SiC wafer by CMP is impractical because of its low polishing rate. Further, both grinding and CMP have difficulty in thinning a recess having a small rectangular area and difficulty in discharging shavings from a recess, and have a problem it is necessary to remove distortion.

Further, power devices are required to have lower on-state resistance and higher withstand voltage; therefore a wafer for such a power device is required to be further thinned.

The present invention has been achieved in view of the above-described circumstances, and an object thereof is to provide a wide-gap semiconductor substrate which enables formation of a device having low power loss while maintaining high mechanical strength, a method for manufacturing such a wide-gap semiconductor substrate, and an apparatus for manufacturing such a wide-gap semiconductor substrate.

### Solution to Problem

The present invention, for achieving the above-described objects, relates to a wide-gap semiconductor substrate (hereinafter in this section, simply referred to as “semiconductor substrate”) for forming a device thereon, the semiconductor substrate having a first substrate region as an inner region having a first thickness, and a second substrate region surrounding an outer periphery of the first substrate region and having a second thickness greater than the first thickness, the device being formed on the first substrate region, the first thickness being not less than 10 μm and not more than 50 μm, and the second thickness being in a range of 100 μm to 350 μm.

Because of having the first substrate region (thin-plate part), which has a thickness not less than 10 μm and not more than 50 μm, formed as an inner region thereof and having the second substrate region (thick-plate part), which has a thickness of 100 μm to 350 μm, formed along the outer periphery of the first substrate region, this semiconductor substrate is effectively prevented from being cracked or warped. Further, this semiconductor substrate enables a device formed on the thin-plate part thereof to have low on-state resistance.

Therefore, it is possible to form a device having low power loss with mechanical strength of the semiconductor substrate maintained at high level.

Further, in the semiconductor substrate described above, it is preferred that the first substrate region is formed by dry etching.

Because of the first substrate region being formed by dry etching, such a semiconductor substrate does not require its back surface to be grinded with abrasives that are expensive and easily worn out.

Therefore, the cost for manufacturing such a semiconductor substrate is greatly reduced as compared with the case of manufacture using abrasives that need to be replaced each time they are worn out.

Further, in the semiconductor substrate described above, it is preferred that the semiconductor substrate is made of silicon carbide (4H—SiC, 6H—SiC, or 3C—SiC), gallium nitride (GaN), gallium oxide (GaO), or diamond (C).

Such a semiconductor substrate has a band gap (2.2 eV or more) greater than a band gap of silicon (1.12 eV). Therefore, this semiconductor substrate enables a device formed on the thin-plate part thereof to have lower on-state resistance, so that the device has lower power loss.

The semiconductor substrate described above is preferably manufactured by a manufacturing apparatus having a configuration as described below. This manufacturing apparatus is configured to etch a semiconductor substrate placed on a platen disposed in a processing chamber by means of plasma generated from an etching gas so that only a device formation region of the semiconductor substrate is thinned, the apparatus including an outer-periphery covering mechanism including a cover member covering only a peripheral edge portion of the semiconductor substrate placed on the platen during etching of the semiconductor substrate, the outer-periphery covering mechanism being configured to cause only the device formation region not covered by the cover member to be thinned by etching.

This manufacturing apparatus includes the outer-periphery covering mechanism that covers only a peripheral edge portion of a semiconductor substrate placed on the platen with the cover member during etching of the semiconductor substrate so that only the peripheral edge portion of the semiconductor substrate is not etched. Therefore, the cover member functions as a mask, so that only the peripheral edge portion of the semiconductor substrate is not etched and only the device formation region of the semiconductor substrate is etched. Thus, with this manufacturing apparatus, it is easy to thin only an inner region, where a device is formed, of a semiconductor substrate. Further, thinning only the inner region enables the semiconductor substrate to be effectively prevented from being cracked or warped. Furthermore, the thus-manufactured semiconductor substrate enables a device formed on the thin-plate part thereof to have low on-state resistance.

Further, this manufacturing apparatus may have a configuration in which the outer-periphery covering mechanism further includes a support member provided in the processing chamber to support the cover member and the support member supports the cover member with a gap formed between the cover member and the semiconductor substrate. Further, it is preferred that the gap is set to be not less than 0.5 mm and not more than 3 mm.

Further, in the manufacturing apparatus described above, it is preferred that the outer-periphery covering mechanism further includes a support member provided in the processing chamber to support the cover member and the outer-periphery covering mechanism is configured such that the cover member is brought into contact with and raised by the peripheral edge portion of the semiconductor substrate when the semiconductor substrate is lifted by the platen, thereby covering only the peripheral edge portion of the semiconductor substrate placed on the platen so that only the peripheral edge portion is not etched.

Further, in the manufacturing apparatus described above, it is preferred that the manufacturing apparatus further includes a depth monitor detecting a depth of etching of the semiconductor substrate and the depth monitor includes a depth sensor including a light source radiating a light toward an etched surface of the semiconductor substrate and the cover member, and a processing unit calculating the depth of etching based on reflected lights reflected by the etched surface and the cover member.

With such a manufacturing apparatus, it is possible to start etching without carrying out previous steps such as measuring in advance an etching amount and calculating an etching rate (i.e., setting conditions) so as to recognize an etching end point based on the etching rate and an etching time. Therefore, with this manufacturing apparatus, the time for manufacturing the semiconductor substrate is greatly reduced.

Further, in the manufacturing apparatus described above, it is preferred that the semiconductor substrate is made of silicon carbide (4H—SiC, 6H—SiC, or 3C—SiC), gallium nitride (GaN), gallium oxide (GaO), or diamond (C).

Such a semiconductor substrate has a band gap (2.2 eV or more) greater than a band gap of silicon (1.12 eV). Therefore, this semiconductor substrate enables a device formed on the thin-plate part thereof to have lower on-state resistance, so that the device has lower power loss.

The semiconductor substrate described above is preferably manufactured by a manufacturing method including steps as described below. This manufacturing method is configured to etch a semiconductor substrate placed on a platen disposed in a processing chamber by means of plasma generated from an etching gas so that only a device formation region of the semiconductor substrate is thinned, the method including:

placing the semiconductor substrate onto the platen disposed in the processing chamber and covering with a cover member only a peripheral edge portion where no device is formed of the semiconductor substrate;

supplying the etching gas into the processing chamber and generating the plasma from the etching gas; and

applying a bias potential to the platen to etch only the device formation region of the semiconductor substrate so as to thin only the device formation region.

In this manufacturing method, only a peripheral edge portion of a semiconductor substrate placed on a platen is covered with a cover member during etching of the semiconductor substrate so that only the peripheral edge portion is not etched; therefore, only the peripheral edge portion of the semiconductor substrate is not etched. Thus, with this manufacturing method, a semiconductor substrate is manufactured which has a thin-plate part formed at an inner region thereof and has a thick-plate part formed along an outer periphery of the thin-plate part. Such a semiconductor substrate is effectively prevented from being cracked or warped. Further, a device manufactured by forming it on the thin-plate part of such a semiconductor substrate has low on-state resistance.

Note that, in this manufacturing method, it is preferred that a gap is formed between the semiconductor substrate and the cover member. In the case where the cover member is in contact with the semiconductor substrate when the semiconductor substrate is etched in a state where a bias potential is applied to the platen, depending on the material of the cover member, a bias potential is generated in the cover member. This causes a problem that the cover member is sputtered by ions in the plasma and the product of the sputtering adheres to the surface of the inner region, i.e., the surface of the thin-plat part, of the semiconductor substrate, which deteriorates surface accuracy of the surface of the thin-plat part. Forming a gap between the semiconductor substrate and the cover member enables prevention of generation of a bias potential in the cover member, which prevents the surface accuracy of the surface of the thin-plate part from being deteriorated due to the cover member being sputtered.

It is preferred that the gap between the semiconductor substrate and the cover member is not less than 0.5 mm and not more than 3 mm. In the case where the gap is smaller than 0.5 mm, generation of a bias potential in the cover member is not effectively prevented. In the case where the gap is equal to or greater than 3 mm, an etching species enters between the semiconductor substrate and the cover member and etches the region covered by the cover member (the second substrate region) of the semiconductor substrate, which results in deterioration of the shape of the semiconductor substrate obtained, such as an inner peripheral edge (inner shoulder) of the second substrate region (the thick-plate part) being etched.

Further, it is preferred that the cover member is made of quartz, aluminum oxide, or yttria or made of a material made by coating quartz, aluminum oxide, or yttria with a metal coating. Using aluminum oxide is disadvantageous in that sputtering as described above is likely to occur and such sputtering leads to deterioration of the surface accuracy of the surface of the thin-plate part, while it is advantageous in that the cover member is inexpensive to manufacture. Using yttria is disadvantageous in that the cover member is expensive to manufacture, while it is advantageous in that, even when sputtering as described above occurs, the product of the sputtering is likely to disappear and therefore the surface accuracy of the surface of the thin-plate part is less deteriorated. Further, using quartz is advantageous in that the cover member is less expensive to manufacture than in the case of using yttria and in that, even when sputtering as described above occurs, the product of the sputtering disappears and therefore the surface accuracy of the surface of the thin-plate part is hardly deteriorated. In the case of using quartz, although the cover member is etched by an etching species, loading is alleviated by the etching of the cover member, so that the thin-plate part is etched to have a uniform thickness.

In this manufacturing method, it is preferred that the semiconductor substrate is etched to have a thickness of 50 μm or less.

In such a manufacturing method, the device formation region of the semiconductor substrate is etched to have a thickness of 50 μm or less. Therefore, this manufacturing method enables a device formed in the thinned region to have lower on-state resistance, so that the device has lower power loss.

In this manufacturing method, it is preferred that the etching gas includes a fluorine-containing gas.

In this manufacturing method, it is preferred that the bias potential is applied to the platen by supplying an RF power of 500 W or more to the platen and a pressure inside the processing chamber is 30 Pa or less.

Because of the bias potential being applied to the platen by supplying an RF power of 500 W or more to the platen, such a manufacturing method etches even a semiconductor substrate with strong interatomic bonding rapidly. Further, because the pressure inside the processing chamber is 30 Pa or less, the plasma is stabilized and in-plane uniformity of the amount of etching is thereby enhanced.

In this manufacturing method, it is preferred that the semiconductor substrate is made of silicon carbide (4H—SiC, 6H—SiC, or 3C—SiC), gallium nitride (GaN), gallium oxide (GaO), or diamond (C).

In such a manufacturing method, the semiconductor substrate has a band gap (2.2 eV or more) greater than a band gap of silicon (1.12 eV). Therefore, a device formed on the thin-plate part of the semiconductor substrate has lower on-state resistance, so that the device has lower power loss.

### Advantageous Effects of Invention

As described above, the wide-gap semiconductor substrate according to the present invention has a thin-plate part formed at an inner region thereof where a device is formed, and has a thick-plate part formed along an outer periphery of the thin-plate part. With this semiconductor substrate, it is possible to form a device having low power loss with mechanical strength of the semiconductor substrate maintained at high level.

Further, the wide-gap semiconductor substrate manufacturing apparatus according to the present invention is configured such that only a peripheral edge portion of a wide-gap semiconductor substrate is covered so that only the peripheral edge portion is not etched; therefore, only the peripheral edge portion of the wide-gap semiconductor substrate is not etched. With this manufacturing apparatus, it is easy to thin only an inner region, where a device is formed, of a wide-gap semiconductor substrate.

Furthermore, the wide-gap semiconductor substrate manufacturing method according to the present invention is configured such that only a peripheral edge portion of a wide-gap semiconductor substrate is covered during etching of the wide-gap semiconductor substrate so that only the peripheral edge portion is not etched. With this manufacturing method, it is easy to thin only an inner region, where a device is formed, of a wide-gap semiconductor substrate.

### BRIEF DESCRIPTION OF DRAWINGS

FIG. 1 shows (a) a vertical sectional view of a semiconductor substrate according to a first embodiment of the present invention, and (b) a plan view of the semiconductor substrate;

FIG. 2 is a sectional view of a schematic configuration of an etching apparatus (manufacturing apparatus) used for manufacturing the semiconductor substrate illustrated in FIG. 1;

FIG. 3 shows vertical sectional views showing steps of a method of manufacturing the semiconductor substrate illustrated in FIG. 1;

FIG. 4 shows vertical sectional views showing steps of the method of manufacturing the semiconductor substrate illustrated in FIG. 1;

FIG. 5 is a vertical sectional view of a schematic configuration of an etching apparatus (manufacturing apparatus) according to a second embodiment of the present invention;

FIG. 6 is a diagram illustrative of a manufacturing method and a manufacturing apparatus according to another embodiment of the present invention;

FIG. 7 is a plan view of a wide-gap semiconductor substrate according to another embodiment of the present invention; and

FIG. 8 is a plan view of a cover member used for manufacturing the wide-gap semiconductor substrate illustrated in FIG. 7.

### DESCRIPTION OF EMBODIMENTS

Hereinafter, embodiments of the present invention will be described with reference to the drawings.

### First Embodiment

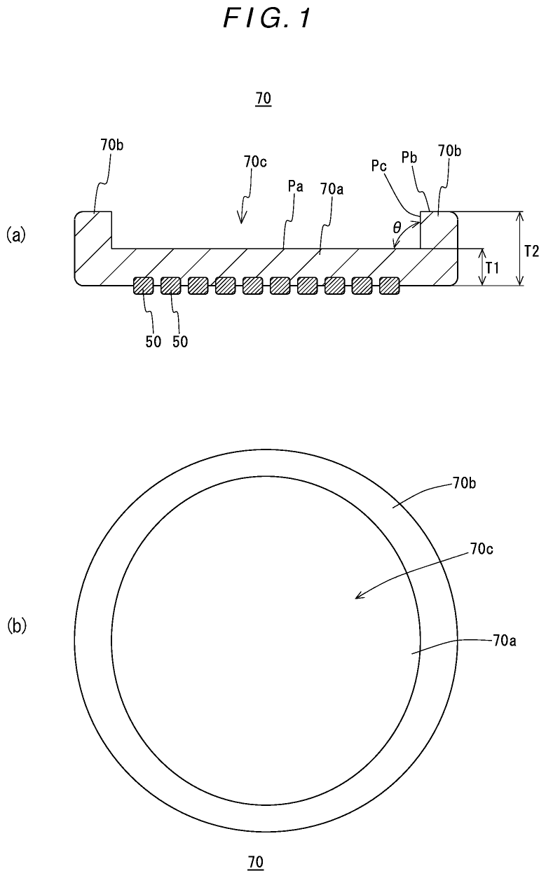

FIG. 1(a) is a vertical sectional view of a semiconductor substrate 70 according to a first embodiment of the present invention. FIG. 1(b) is a plan view of the semiconductor substrate 70. The semiconductor substrate 70 is a wide-gap semiconductor substrate made of silicon carbide (4H—SiC) having high voltage withstanding properties. An electronic device manufactured with this semiconductor substrate 70 has low power loss, which is used as a high-performance and power-saving inverter, power module for household electrical appliance, or power semiconductor device for electric vehicle.

Further, silicon carbide has a higher Young's modulus than silicon and has the property of having high yield temperature even in a high-temperature environment. Therefore, silicon carbide is used as an MEMS (Micro-Electro Mechanical Systems) device having both electric circuit elements and fine mechanical elements, which is currently used in an acceleration sensor, a printer head, a pressure sensor, a DMD (Digital Micromirror Device), etc. and the market scale of which is increasingly expanded.

As shown in FIGS. 1(a) and 1(b), the semiconductor substrate 70 according to this embodiment consists of a thin-plate part (first substrate region) 70a as an inner region having a circular shape in plan view and having a thickness T1 (not less than 10 μm and not more than 50 μm), and a thick-plate part (second substrate region) 70b as an outer annular region formed along the outer periphery of the thin-plate part 70a and having a thickness T2 (>T1). That is to say, the semiconductor substrate 70 has a recess 70c having a circular shape in plan view and formed at a region corresponding to the thin-plate part 70a as the inner region. The thick-plate part 70b is formed to be concentric with the thin-plate part 70a and surround the outer periphery of the thin-plate part 70a. Note that the recess 70c may have any area, which is determined in accordance with a mechanical strength the semiconductor substrate 70 is required to have.

As shown in FIG. 1(a), an angle θ formed by a planar surface Pa of the thin-plate part 70a and a plane (an inner peripheral surface of the thick-plate part 70b) connecting the planar surface Pa to a planar surface Pb of the thick-plate part 70b is approximately a right angle.

As shown in FIG. 1(a), devices 50 each having a size of several mm square are formed on a surface opposite to the surface Pa of the thin-plate part 70a (i.e., a back surface of the thin-plate part 70a that is illustrated as a lower surface in FIG. 1(a)). The devices 50 include vertical power devices (an insulated gate bipolar transistor (IGBT), an MOS field effect transistor (MOSFET), a diode, etc.).

The thick-plate part 70b as the outer region serves to maintain mechanical strength of the semiconductor substrate 70 so as to prevent the semiconductor substrate 70 from being cracked or warped while it is conveyed or subjected to heat treatment. For example, the thickness T2 of the thick-plate part 70b is in a range of 100 μm to 350 μm. Setting the thickness T2 in this range enables the semiconductor substrate 70 to be effectively prevented from being cracked or warped. In contrast, the thin-plate part 70a has the thickness T1 not less than 10 μm and not more than 50 μm. Setting the thickness T1 in this range enables the devices 50 formed on the surface of the thin-plate part 70a to have low on-state resistance, while the mechanical strength of the semiconductor substrate 70 is maintained at high level. Therefore, it is possible to manufacture a device having lower power loss with the mechanical strength of the semiconductor substrate 70 maintained at high level.

Note that the recess 70c in the example described here has a circular planer shape; however, the present invention is not limited thereto. For example, the planar shape of the recess 70c may be a rectangular shape, a rounded quadrangular shape (quadrangular shape with rounded corners), a polygonal shape, etc. The recess 70c may have any planar shape which is appropriate to the shapes of devices to be formed. Such a configuration also provides the same effects as the example described here. Further, the angle θ in this embodiment is approximately a right angle (90 degrees); however, the present invention is not limited thereto. The angle θ may be an acute angle or an obtuse angle. Such a configuration also provides the same effects as the example described here. Furthermore, this embodiment describes an example configuration in which one recess is formed; however, a configuration is possible in which two or more recesses are formed.

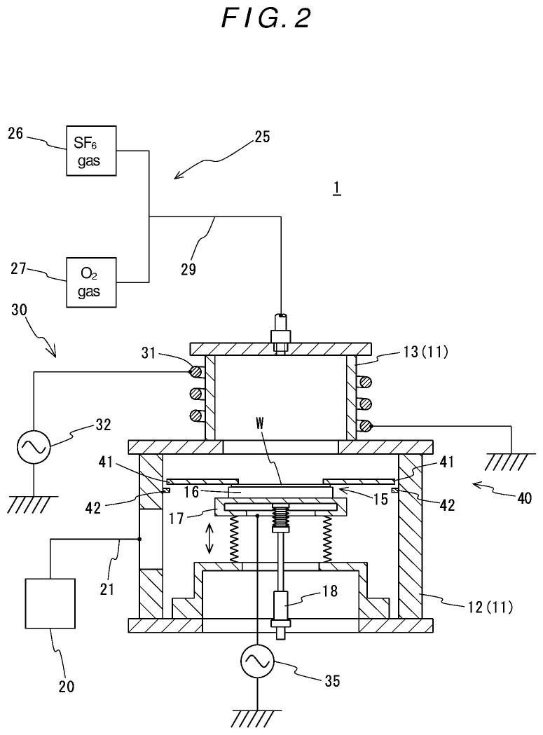

Next, an etching apparatus 1, which is a manufacturing apparatus for manufacturing the semiconductor substrate 70 according to this embodiment, is described with reference to FIG. 2. FIG. 2 is a sectional view of a schematic configuration of the etching apparatus 1 used for manufacturing the semiconductor substrate 70 illustrated in FIG. 1.

As shown in FIG. 2, the etching apparatus 1 includes a processing chamber 11 having a closed space, a platen 15 which is disposed in the processing chamber 11 in such a manner that it is able to be lifted and lowered and on which a wafer W to be etched is to be placed, a lifting cylinder (lifting device) 18 lifting and lowering the platen 15, an exhaust device 20 reducing the pressure inside the processing chamber 11, a gas supply device (processing gas supply unit) 25 supplying a processing gas into the processing chamber 11, a plasma generating device 30 generating plasma from the processing gas supplied into the processing chamber 11, an RF power supply (substrate power supply unit) 35 supplying RF power to the platen 15, and an outer-periphery covering mechanism 40 covering a peripheral edge portion (non-etched portion) of the wafer W. This etching apparatus 1 etches a wafer W placed on the platen 15 disposed in the processing chamber 11 by means of plasma generated from an etching gas so that only a device formation region of the wafer W, where a device is to be formed, is thinned. Note that the outer-periphery covering mechanism 40 functions to cover only the peripheral edge portion of the wafer W placed on the platen 15 during etching of the wafer W so that only the peripheral edge portion is not etched.

The processing chamber 11 is composed of a lower chamber 12 and an upper chamber 13, interior spaces of which communicate with each other. The upper chamber 13 is formed to be smaller than the lower chamber 12. The platen 15 is composed of an upper member 16 on which a wafer W is to be formed, and a lower member 17 to which the lifting cylinder 18 is connected. The platen 15 is disposed in the lower chamber 12.

The outer-periphery covering mechanism 40 includes a cover member 41 and a support member 42. The cover member 41 is disposed in the lower chamber 12 and has an annular (doughnut) shape in plan view so as to cover only a peripheral edge portion of the wafer W placed on the platen 15 when the platen 15 is lifted, thereby functioning as a mask for etching. The support member 42 is formed annularly on an inner wall of the lower chamber 12 to support the cover member 41. The support member 42 is configured to support an outer peripheral edge of the cover member 41. Note that this embodiment is configured such that the cover member 42 supports the cover member 41 at the entire outer peripheral edge of the support member 41; however, the present invention is not limited thereto. For example, a configuration is possible in which inwardly protruding members are provided at several (for example, four) positions on the inner wall of the lower chamber 12 and the cover member 41 is supported by the inwardly protruding members. Note further that this embodiment is configured such that the platen 15 on which a wafer W is to be placed is lifted and lowered; however, the present invention is not limited thereto. A configuration is possible in which the platen 15 is fixed and the cover member 41 is lifted and lowered instead. Note further that the outer-periphery covering mechanism 40 in the example described here is configured to have a shape which allows the recess 70c to be etched to have a circular planar shape; however, the present invention is not limited thereto. For example, the outer-periphery covering mechanism 40 may be configured to allow the recess 70c to be etched to have a non-circular planar shape, such as a rectangular planar shape, a rounded quadrangular planar shape (quadrangular planar shape with rounded corners), or a polygonal planar shape. Thus, the recess 70c can be formed into any shape by changing the shape of the cover member 41. Further, the problem of shavings produced in grinding or the like is avoided.

The cover member 41 is made of a ceramic material, such as alumina (aluminum oxide), in view of etching selectivity of the cover member 41 and the wafer W. However, the present invention is not limited thereto. The cover member 41 may be made of yttrium or a material having a low dielectric constant, such as quartz. Alternatively, the cover member 41 may be made of a material made by coating alumna, quartz, or yttrium with a metal coating such as a nickel coating.

Using aluminum oxide is disadvantageous in that sputtering is likely to occur in an etching process as described later and such sputtering leads to deterioration of surface accuracy of the surface Pa of the thin-plate part 70a, while it is advantageous in that the cover member 41 is inexpensive to manufacture. Using yttria is disadvantageous in that the cover member 41 is expensive to manufacture, while it is advantageous in that, even when sputtering as described above occurs, the product of the sputtering is likely to disappear and therefore the surface accuracy of the surface Pa of the thin-plate part 70a is less deteriorated. Using quartz is advantageous in that the cover member 41 is less expensive to manufacture than in the case of using yttria and in that, even when sputtering as described above occurs, the product of the sputtering disappears and therefore the surface accuracy of the surface Pa of the thin-plate part 70a is hardly deteriorated. In the case of using quartz, although the cover member 41 is etched by an etching species, loading is alleviated by the etching of the cover member 41, so that the thin-plate part 70a is etched to have a uniform thickness.

Next, operation of the outer-periphery covering mechanism 40 is described.

First, when the platen 15 has been lowered by the lifting cylinder 18, the cover member 41 is supported by the support member 42 at the outer peripheral edge thereof. In this state, a wafer W, which is not yet etched, is placed onto the platen 15. Subsequently, the platen 15 and the wafer W placed thereon are lifted by the lifting cylinder 18 for an etching process, whereby the cover member 41 is brought into contact with an upper surface of a peripheral edge portion of the wafer W and then the cover member 41 is raised along with the lifted wafer W. In this process, only the peripheral edge portion of the wafer W placed on the platen 15 is covered by the cover member 41. The cover member 41 functions as a mask in the etching process.

After the etching process is finished, the platen 15 is lowered by the lifting cylinder 18, whereby the cover member 41 is supported by the support member 42. In this state, the etched wafer W (semiconductor substrate 70) is unloaded from the etching apparatus 1, and a wafer W to be etched next is loaded into the etching apparatus 1 and placed onto the platen 15.

Using this outer-periphery covering member 40 allows an outer peripheral area of a width of about 3 mm of the upper surface of the wafer W to remain unetched, so that only an inner area of the upper surface of the wafer W is etched and thereby the inner region of the wafer W is thinned. This configuration enables reduction of cracking and warpage of the etched wafer W (semiconductor substrate 70).

Note that this embodiment is configured such that a wafer W is placed onto the upper member 16; however, the present invention is not limited thereto. For example, a configuration is possible in which an electrostatic chuck having an electrode plate clamped between a pair of insulating layers is used and an appropriate voltage is applied to the electrode plate so that a wafer W is attracted to and held on the electrostatic chuck. Such a configuration also provides the same effects as this embodiment.

The exhaust device 20 includes an exhaust pipe 21 connected to a side surface of the lower chamber 12. The exhaust device 20 exhausts gas from the processing chamber 11 through the exhaust pipe 21 to set the pressure inside the processing chamber 11 to a predetermined pressure.

The gas supply device 25 includes a gas supply unit 26 supplying SF₆ gas as a fluorine-containing gas, a gas supply unit 27 supplying O₂ gas as an oxygen-containing gas, and a supply pipe 29 which is at one end connected to an upper surface of the upper chamber 13 and at the other end branched and connected to the gas supply units 26 and 27. The SF₆ gas and O₂ gas supplied from the gas supply units 26 and 27 are supplied as the processing gas into the processing chamber 11 through the supply pipe 29.

The plasma generating device 30 generates so-called inductively coupled plasma (ICP). The plasma generating device 30 consists of a spiral (annular) coil 31 disposed on the upper chamber 13 and an RF power supply (coil power supply unit) 32 supplying RF power to the coil 31. By RF power being supplied to the coil 31 by the RF power supply unit 32, plasma is generated from the processing gas supplied in the upper chamber 13.

The RF power supply 35 supplies RF power to the platen 15 to produce a potential difference (bias potential) between the platen 15 and plasma, thereby making ions generated by the generation of plasma from the processing gas incident to the wafer W. Thereby, the wafer W is etched. Etching herein means dry etching (anisotropic etching or isotropic etching) or the like, such as RIE (Reactive Ion Etching) using a reaction gas.

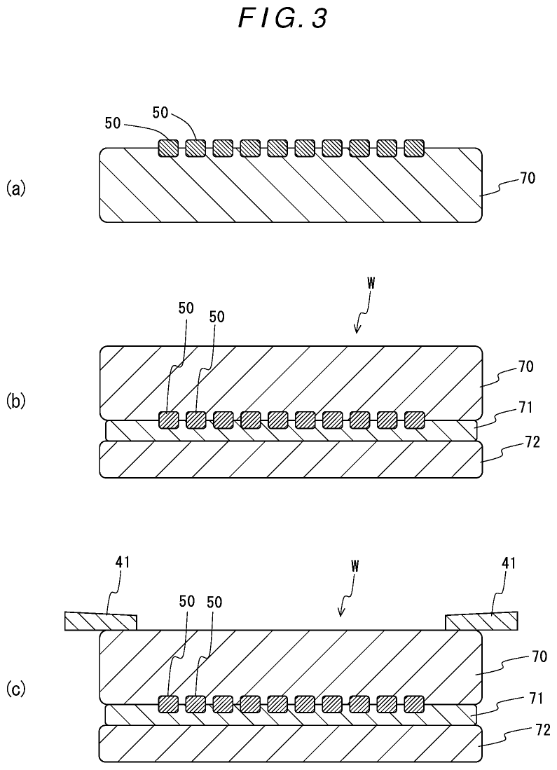

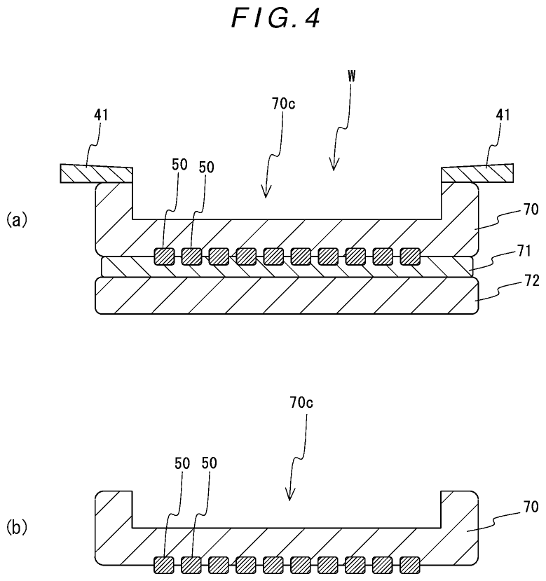

FIGS. 3 and 4 shows vertical sectional views showing steps of a method of manufacturing the semiconductor substrate 70 illustrated in FIG. 1. The method of manufacturing the semiconductor substrate 70 is now described below with reference to FIGS. 3 and 4.

First, a wafer W is manufactured in accordance with the following steps. That is to say, as shown in FIG. 3(a), a semiconductor substrate 70 having devices 50 formed on one surface thereof is prepared. This semiconductor substrate 70 has a typical circular-plate shape (having a thickness of 0.35 mm with respect to a diameter of 76 mm to 150 mm) and is made of silicon carbide.

Subsequently, as shown in FIG. 3(b), an adhesive 71 is applied on the entire surface having the devices 50 formed thereon with an applier (not illustrated). For example, a spin coating method is used in which the semiconductor substrate 70 is rotated at high speed so that the adhesive 71, which is dropped, is spread over the entire surface having the devices 50 formed thereon by centrifugal force. Therefore, it is preferred that the adhesive 71 has an appropriate viscosity and is dropped in a liquid state onto the semiconductor substrate 70. For example, a polyimide adhesive or an acrylic adhesive is used as the adhesive 71. Subsequently, a carrier substrate 72 is affixed to the semiconductor substrate 70 via the adhesive 71. This carrier substrate 72 protects the devices 50. Note that the devices 50 may be protected by, for example, only a protective coating material without affixing the carrier substrate 72. In such a case, it is unnecessary to affix the carrier substrate 72.

The configuration described above enables the carrier substrate 72 (see FIG. 3(c)) to be affixed to the semiconductor substrate 70 with the surface having the devices 50 formed thereon protected. The configuration further makes it easy to remove the carrier substrate 72 after the semiconductor substrate 70 is thinned.

Thereafter, the wafer W is loaded into the processing chamber 11 of the etching apparatus 1 and placed onto the platen 15 (the upper member 16) such that the surface not having the devices 50 formed thereon faces upward as an upper surface. When this process is carried out, the platen 15 has been lowered and the cover member 41 is supported by the support member 42. Subsequently, as shown in FIG. 3(c), the wafer W is lifted together with the platen 15, and simultaneously the cover member 41 is raised via an outer peripheral edge of the wafer W. Thereby, a peripheral portion of a width of about 3 mm of the upper surface of the wafer W is masked by the cover member 41. By plasma etching the wafer W in this state, only the area inside the peripheral portion of the upper surface of the wafer W is etched with only the peripheral portion remaining unetched. That is to say, it is possible to thin an inner region of the wafer W. Note that it is preferred that the inner diameter of the cover member 41 is determined such that a peripheral portion of a radial width of 1 mm to 10 mm of the upper surface of the semiconductor substrate 70 is covered by the cover member 41, in other words, so that the thick-plate part (second substrate region) 70b of the semiconductor substrate 70 has a radial width of 1 mm to 10 mm. This is because the thick-plate part 70b as having a width smaller than 1 mm makes the semiconductor substrate 70 insufficient in strength, while the thick-plate part 70b as having a width greater than 10 mm makes an effective area for device formation. Particularly, the effective area greatly depends on the shape and size of each device, arrangement of the devices, and the shape of the recess 70c where the devices are formed. In the case where the recess 70c has a circular planar shape, it is preferred that the thick-plate part 70b has a width of 5 mm or less. In the case where the recess 70c has a polygonal planar shape, in some cases, the semiconductor substrate 70 has a sufficient effective area for device formation even when the thick-plate part 70b has a width of 5 mm or more.

Subsequently, as shown in FIG. 4(a), the upper surface of the semiconductor substrate 70 is etched by a plasma etching technology, e.g., RIE (Reactive Ion Etching), with the cover member 41 used as a mask so that the recess 70c is formed. The conditions for the etching are as follows: SF₆ gas as an etching gas is supplied into the processing chamber 11 at a flow rate of 400 sccm; O₂ gas as an additive gas is supplied into the processing chamber 11 at a flow rate of 600 sccm; coil power supplied to the coil 31 is 2000 W; bias power supplied to the platen 15 is 700 W; and the pressure inside the processing chamber 11 is 12 Pa. Under these conditions, etching rate is approximately 6 μm/min. The O₂ gas as an additive gas is expected to provide the effect of enhancing reactivity with carbon (C) in silicon carbide (SiC) so as to increase the etching rate. Note that, although O₂ gas is used as an additive gas in the etching above, the semiconductor substrate 70 may be etched by using only SF₆ gas as an etching gas without using O₂ gas.

Note that the coil power can be set in a range of 400 to 5000 W. In view of plasma stability, it is particularly preferred that it is 1500 W or more. Further, the bias power can be set in a range of 50 to 1000 W. In view of plasma stability, it is particularly preferred that it is 500 W or more. The pressure inside the processing chamber 11 can be set in a range of 0.5 to 50 Pa. In view of the in-plane uniformity of etching amount, it is particularly preferred that it is 3 Pa or more up to 30 Pa.

After the upper surface of the semiconductor substrate 71 is etched in the above-described manner and thereby the recess 70c having a predetermined depth is formed, the etching process is ended and the wafer W is unloaded from the processing chamber 11. Thereafter, a backside electrode is formed with a sputtering device or the like.

Differently from the conventional art, this thinning method does not require grinding. Therefore, it is unnecessary to carry out a stress relief process using CMP or the like in order to remove grinding distortion, such as a damaged layer, generated in grinding, which enables reduction of manufacturing time and manufacturing cost. Furthermore, even thinning of a recess with a small rectangular area can be facilitated by changing the shape of the cover.

Note that this embodiment is configured such that the etching apparatus 1 has a mechanism for covering the non-etched portion of the wafer W; however, the present invention is not limited thereto. For example, a configuration is possible in which a mechanism for covering the non-etched portion of the wafer W is attached to the wafer W.

Thereafter, as shown in FIG. 4(b), the carrier substrate 72 is peeled off from the adhesive 71 and then the adhesive 71 is removed.

The semiconductor substrate 70 according to this embodiment that is manufactured in the above-described manner has a large thickness at its outer peripheral portion (second substrate region) and has a small thickness only at its inner region (first substrate region) for device formation. Therefore, cracking and warpage of the semiconductor substrate 70 are reduced. Further, since the semiconductor substrate 70, on which the devices 50 are formed, is made of silicon carbide and has a minimum thickness (not less than 10 μm and not more than 50 μm) as well as high withstand voltage, the devices 50 have lower power loss than a device manufactured with silicon.

Further, the manufacturing method according to this embodiment for manufacturing the semiconductor substrate 70, the semiconductor substrate 70 made of silicon carbide that has high hardness can be thinned to a minimum thickness (not less than 10 μm and not more than 50 μm) having high voltage withstanding property by a plasma etching method without depending on mechanical grinding. Therefore, expensive abrasives for grinding are not needed, which greatly reduces manufacturing cost.

### Second Embodiment

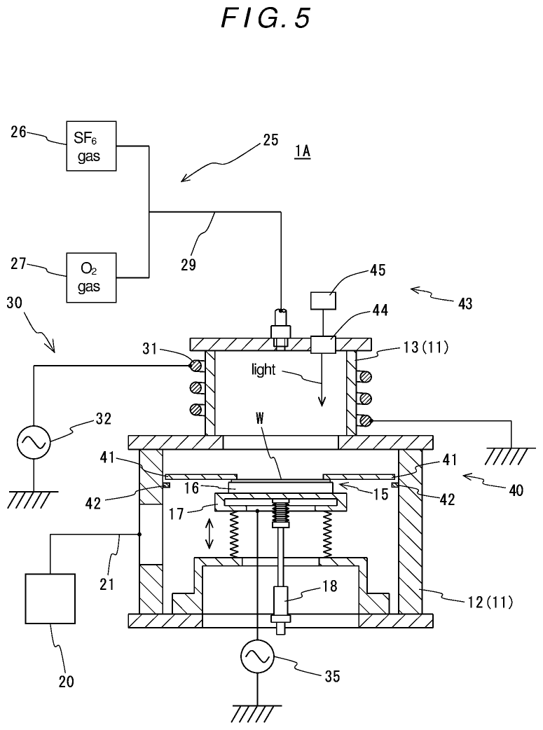

Next, a second embodiment of the present invention is described based on FIG. 5. FIG. 5 is a sectional view of a schematic configuration of an etching apparatus 1A according to the second embodiment. The etching apparatus 1A is different from the etching apparatus 1 illustrated in FIG. 2 in that the etching apparatus 1A is configured to further include a spectroscopic depth monitor 43 which is capable of measuring (monitoring) the depth of etching of a wafer W in real time. Accordingly, in FIG. 5, components identical to those of the etching apparatus 1 illustrated in FIG. 2 are denoted by the same reference numerals as in FIG. 2 and detailed description thereof is omitted in the description below.

The depth monitor 43 includes a depth sensor 44 and a processing unit 45. The depth sensor 44 includes a multi-wavelength light source (not illustrated) radiating a white light toward the surface to be etched of the wafer W and the cover member 41, a light receiving unit (not illustrated) receiving reflected lights from the wafer W and the cover member 41, and a spectrophotometer (not illustrated). The depth sensor 44 obtains a depth signal which changes in accordance with the depth of etching, and outputs the obtained depth signal to the processing unit 45.

The depth sensor 44 is embedded in the upper surface of the upper chamber 13 and arranged to face the surface of the wafer W and the surface of the cover member 41. During etching of the wafer W, a white light is radiated from the light source toward the wafer W and the cover member 41, and reflected lights from the wafer W and the cover member 41 are received by the light receiving unit. The spectrophotometer measures intensity of light at each wavelength in a predetermined wavelength range for each of the reflected lights and transmits light intensity data obtained to the processing unit 45. The light intensity data is a depth signal in which the depth of etching is reflected and which changes in accordance with the depth of etching. The processing unit 45 generates based on the light intensity data a spectrum representing the intensity of light at each wavelength, and uses the generated spectrum to calculate the depth of etching based on a phase difference between the reflected light reflected by the etched surface of the wafer W and the reflected light reflected by the cover member 41.

Note that the reflected light reflected by the wafer W and the reflected light reflected by the cover member 41 interfere with each other. The manner of interference between their light waves changes in accordance with the depth of the wafer W; therefore, this change of the manner of interference can be used to calculate the depth of etching.

The method of manufacturing the semiconductor substrate 70 with the etching apparatus A1 according to this embodiment provides the same effects as the manufacturing method using the etching apparatus 1 according to the first embodiment. Further, the etching apparatus A1 according to this embodiment is capable of monitoring the etching depth in real time; therefore, the etching apparatus 1A can start etching without carrying out previous steps such as measuring in advance an etching amount and calculating an etching rate so as to recognize an etching end point based on the etching rate and an etching time. Therefore, as compared with the etching apparatus 1 according to the first embodiment, the etching apparatus 1A according to this embodiment greatly reduces the manufacturing time.

Hereinbefore, specific embodiments of the present invention have been described. However, the present invention is not limited to the embodiments described above and can be implemented differently.

For example, in the above embodiments, silicon carbide having a crystal structure of 4H—SiC is used as the semiconductor substrate 70. However, the material of the semiconductor substrate 70 is not limited to such silicon carbide and may be, for example, silicon carbide having a crystal structure other than 4H—SiC (6H—SiC or 3C—SiC), gallium nitride (GaN), gallium oxide (GaO), or diamond (C). In such cases, the same effects as those in the above embodiments are provided.

Further, in the above embodiments, the semiconductor substrate according to the present invention is manufactured by using the etching apparatus 1 or the etching apparatus 1A. However, the manufacturing method according to the present invention may be implemented by using an etching apparatus configured differently from them. Further, the above embodiments are configured such that the devices 50 are first formed on the semiconductor substrate 70 and then the inner region (first substrate region), where the devices 50 are formed, of the semiconductor substrate 70 is thinned. However, the present invention is not limited to such a configuration. For example, a configuration is possible in which the inner region (first substrate region) of the semiconductor substrate 70 is first thinned and then the devices 50 are formed in the thinned region (thin-plate part) of the semiconductor substrate 70.

Further, instead of the fluorine-containing gas (SF₆ gas) used as the etching gas in the above embodiments, for example, a chlorine-containing gas, such as Cl₂ gas, BCl₃ gas, CCl₄ gas, or SiCl₄ gas, may be used. The manufacturing method using such a gas also provides the same effects as the above manufacturing methods.

Further, the foregoing description of the above embodiments describes an example in which the etching apparatus 1, 1A has a covering mechanism provided thereon which covers only a peripheral edge portion of the semiconductor substrate 70 so that only the peripheral edge portion is not etched. However, the present invention is not limited to such a configuration. For example, a configuration is possible in which a case for inserting the wafer W therein is used and the case has a cover provided thereon which covers only a peripheral edge portion of the semiconductor substrate 70 so that only the peripheral edge portion is not etched. Alternatively, a configuration is possible in which an etching mask, such as a photoresist mask, a oxide film mask, or a metal mask, is formed on a peripheral edge portion of the semiconductor substrate 70 so that only the peripheral edge portion is not etched.

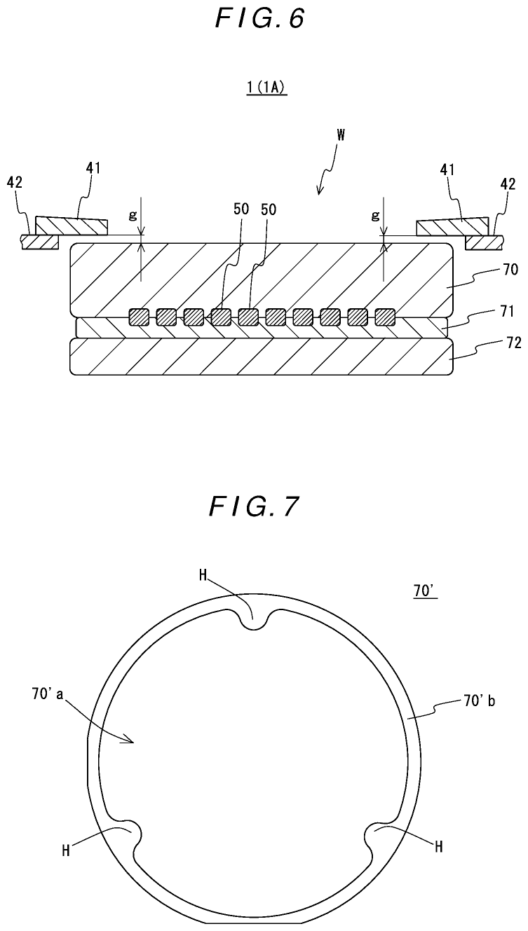

Further, the above embodiments are configured such that etching is performed with the cover member 41 placed on the semiconductor substrate 70. However, the manufacturing apparatus (etching apparatus) and manufacturing method according to the present invention are not limited to such a configuration. As shown in FIG. 6, the etching apparatus A, A1 may be configured such that the cover member 41 is supported by the support member 42 such that a gap g is formed between the upper surface of the semiconductor substrate 70 and the lower surface of the cover member 41 when the platen 15 reaches a lifting end. Further, the manufacturing method may be configured such that etching is performed with the gap g formed between the upper surface of the semiconductor substrate 70 and the lower surface of the cover member 41.

In the case where the cover member 41 is contact with the semiconductor substrate 70 when the semiconductor substrate 70 is etched in a state where a bias potential is applied to the platen 15, depending on the material of the cover member 41 (for example, in the case of alumina), a bias potential is generated in the cover member 41. This causes a problem that the cover member 41 is sputtered by ions in the plasma and the product of the sputtering adheres to the surface of the inner region of the semiconductor substrate 70, i.e., the surface of the thin-plate part 70a (the recess 70c), which deteriorates surface accuracy of the surface of the thin-plate part 70a. Accordingly, a gap g is formed between the semiconductor substrate 70 and the cover member 41 so that a bias potential is not generated in the cover member 41. Thereby, the surface accuracy of the upper surface of the thin-plate part 70a is prevented from being deteriorated due to the cover member 41 being sputtered.

Note that it is preferred that the gap g between the semiconductor substrate 70 and the cover member 41 is not less than 0.5 mm and not more than 3 mm. In the case where the gap g is smaller than 0.5 mm, generation of a bias potential in the cover member 41 is not effectively prevented. In the case where the gap g is equal to or greater than 3 mm, an etching species enters between the semiconductor substrate 70 and the cover member 41 and etches the region covered by the cover member 41 (the second substrate region) of the semiconductor substrate 70, which causes a problem that the shape of the semiconductor substrate 70 obtained is deteriorated, e.g., an inner peripheral edge (inner shoulder) of the second substrate region (thick-plate part) being etched.

Further, the semiconductor substrate 70 may have one or more protrusions which protrude in the radially inward direction from the second substrate region (thick-plate part). A semiconductor substrate having such protrusions is illustrated in FIG. 7. The semiconductor substrate 70′ illustrated in FIG. 7 has three protrusions H, and the three protrusions H are arranged at equal intervals in the circumferential direction of the second substrate region 70′b. For example, if the thin-plate part 70′a is supported by support pins when the semiconductor substrate 70′ is supported at the recess 70′c side in the above-described steps of peeling off the carrier substrate 72 and removing the adhesive 71, the support pins can pierce the supported portions of the thin-plate part 70′a because the thin-plate part 70′a has very small thickness. Accordingly, inwardly protruding protrusions H are formed on the thick-plate part (second substrate region) 70′b so that the protrusions H that has large thickness are supported by the support pins. This configuration can increase the area of the thin-plate part 70′a as much as possible so that the number of devices is increased, and simultaneously can prevent the disadvantage that the semiconductor substrate 70′ is pierced by the support pins. Note that the number of protrusions H provided is not particularly limited. However, in view of stably supporting the semiconductor substrate 70′, it is preferred that three or more protrusions H are formed and the protrusions H are arranged at equal intervals in the circumferential direction of the second substrate region 70′b.

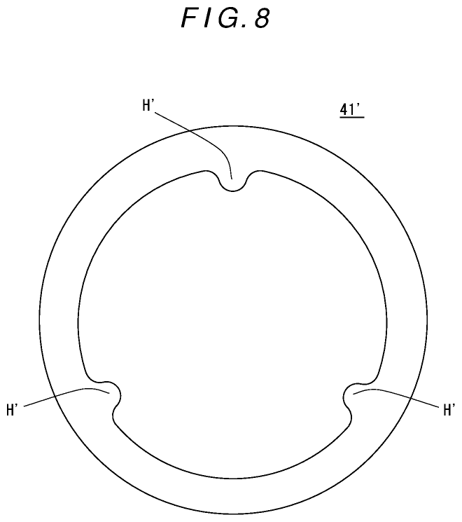

Furthermore, in order to form such protrusions H, the cover member 41 of the above-described etching apparatus A, A1 also needs to have one or more, preferably three or more, protrusions protruding in the radially inward direction. In the case where two or more protrusions are provided, it is preferred that the protrusions are arranged at equal intervals in the circumferential direction. For the sake of clarity, a cover member having such protrusions is illustrated in FIG. 8. In FIG. 8, reference numeral 41′ denotes the cover member and reference numeral H′ denotes the protrusions.

As have been mentioned, the above-described embodiments are given by way of example only, and various modifications are possible without departing from the scope of the present invention.

### REFERENCE SIGNS LIST

1, 1 A Etching apparatus
11 Processing chamber
15 Platen
20 Exhaust device
25 Gas supply device
26, 27 Gas supply unit
30 Plasma generating device
31 Coil
32, 35 RF power supply
41 Cover member
42 Support member
43 Depth monitor
44 Depth sensor
45 Processing unit
50 Device
70 (Wide-gap) semiconductor substrate
70a Thin-plate part (first substrate region)
70b Thick-plate part (second substrate region)
70c Recess
71 Adhesive
72 Carrier substrate
W Wafer

1. A wide-gap semiconductor substrate for forming a device thereon, comprising:
a first substrate region as an inner region having a first thickness; and
a second substrate region surrounding an outer periphery of the first substrate region and having a second thickness greater than the first thickness,
the device being formed on the first substrate region,
the first thickness being not less than 10 μm and not more than 50 μm and
the second substrate region being formed to have the second thickness of 100 μm to 350 μm and set to have a radial width of 1 mm to 10 mm.

2. The wide-gap semiconductor substrate of claim 1, wherein the first substrate region is formed by dry etching.

3. The wide-gap semiconductor substrate of claim 1, wherein the wide-gap semiconductor substrate is made of silicon carbide (4H—SiC, 6H—SiC, or 3C—SiC), gallium nitride (GaN), gallium oxide (GaO), or diamond (C).

4. A wide-gap semiconductor substrate manufacturing apparatus etching a wide-gap semiconductor substrate placed on a platen disposed in a processing chamber by means of plasma generated from an etching gas so that only a device formation region of the wide-gap semiconductor substrate is thinned, characterized by comprising:
an outer-periphery covering mechanism including a cover member covering, during etching of the wide-gap semiconductor substrate, only a peripheral edge portion of the wide-gap semiconductor substrate placed on the platen such that the peripheral edge portion covered has a radial width of 1 mm to 10 mm, and configured to cause only the device formation region not covered by the cover member to be thinned by etching.

5. The wide-gap semiconductor substrate manufacturing apparatus of claim 4, wherein:
the outer-periphery covering mechanism further includes a support member provided in the processing chamber and supporting the cover member; and
the support member supports the cover member such that the cover member covers only the peripheral edge portion of the wide-gap semiconductor substrate with a gap formed between the cover member and the wide-gap semiconductor substrate.

6. The wide-gap semiconductor substrate manufacturing apparatus of claim 5, wherein the support member supports the cover member such that a gap of not less than 0.5 mm and not more than 3 mm is formed between the cover member and the wide-gap semiconductor substrate.

7. The wide-gap semiconductor substrate manufacturing apparatus of claim 4, wherein:
the outer-periphery covering mechanism further includes a support member provided in the processing chamber and supporting the cover member; and
the outer-periphery covering mechanism is configured such that the cover member is brought into contact with and raised by the peripheral edge portion of the wide-gap semiconductor substrate when the wide-gap semiconductor substrate is lifted by the platen, thereby covering only the peripheral edge portion of the wide-gap semiconductor substrate placed on the platen so that only the peripheral edge portion is not etched.

8. The wide-gap semiconductor substrate manufacturing apparatus of claim 4, wherein the cover member is made of quartz, aluminum oxide, or yttria or made of a material made by coating quartz, aluminum oxide, or yttria with a metal coating.

9. The wide-gap semiconductor substrate manufacturing apparatus of claim 4, wherein:
the wide-gap semiconductor substrate manufacturing apparatus further comprises a depth monitor detecting a depth of etching of the wide-gap semiconductor substrate; and
the depth monitor includes:
a depth sensor including a light source radiating a light toward an etched surface of the wide-gap semiconductor substrate and the cover member; and
a processing unit calculating the depth of etching based on reflected lights reflected by the etched surface and the cover member.

10. The wide-gap semiconductor substrate manufacturing apparatus of claim 4, wherein the wide-gap semiconductor substrate is made of silicon carbide (4H—SiC, 6H—SiC, or 3C—SiC), gallium nitride (GaN), gallium oxide (GaO), or diamond (C).

11. A wide-gap semiconductor substrate manufacturing method etching a wide-gap semiconductor substrate placed on a platen disposed in a processing chamber by means of plasma generated from an etching gas so that only a device formation region of the wide-gap semiconductor substrate is thinned, comprising:
placing the wide-gap semiconductor substrate onto the platen disposed in the processing chamber and covering with a cover member only a peripheral edge portion where no device is formed of the wide-gap semiconductor substrate such that the peripheral edge portion covered has a radial width of 1 mm to 10 mm;
supplying the etching gas into the processing chamber and generating the plasma from the etching gas; and
applying a bias potential to the platen to etch only the device formation region of the semiconductor substrate so as to thin only the device formation region.

12. The wide-gap semiconductor substrate manufacturing method of claim 11, wherein a gap is formed between the wide-gap semiconductor substrate and the cover member.

13. The wide-gap semiconductor substrate manufacturing method of claim 12, wherein a gap of not less than 0.5 mm and not more than 3 mm is formed between the wide-gap semiconductor substrate and the cover member.

14. The wide-gap semiconductor substrate manufacturing method of claim 11, wherein the cover member is made of quartz, aluminum oxide, or yttria or made of a material made by coating quartz, aluminum oxide, or yttria with a metal coating.

15. The wide-gap semiconductor substrate manufacturing method of claim 11, wherein the wide-gap semiconductor substrate is etched to have a thickness of 50 μm or less.

16. The wide-gap semiconductor substrate manufacturing method of claim 11, wherein the etching gas includes a fluorine-containing gas.

17. The wide-gap semiconductor substrate manufacturing method of claim 11, wherein:
the bias potential is applied to the platen by supplying an RF power of 500 W or more to the platen; and
a pressure inside the processing chamber is 30 Pa or less.

18. The wide-gap semiconductor substrate manufacturing method of claim 11, wherein the wide-gap semiconductor substrate is made of silicon carbide (4H—SiC, 6H—SiC, or 3C—SiC), gallium nitride (GaN), gallium oxide (GaO), or diamond (C).
